(19) United States
(12) Patent Application Publication
(10) Pub. No.: US 2013/0128362 A1
(43) Pub. Date: May 23, 2013

(54) MICRO/NANO COMBINED STRUCTURE, MANUFACTURING METHOD OF MICRO/NANO COMBINED STRUCTURE, AND MANUFACTURING METHOD OF AN OPTICAL DEVICE HAVING A MICRO/NANO COMBINED STRUCTURE INTEGRATED THEREWITH

(71) Applicants: Young Min Song, Buk-gu (KR); Yong Tak Lee, Buk-gu (KR)

(72) Inventors: Young Min Song, Buk-gu (KR); Yong Tak Lee, Buk-gu (KR)

(73) Assignee: GWANGJU INSTITUTE OF SCIENCE AND TECHNOLOGY, Buk-gu, Gwangju (KR)

(21) Appl. No.: 13/813,063

(22) PCT Filed: Jul. 29, 2011
(86) PCT No.: PCT/KR2011/005625

§ 371 Date: Jan. 29, 2013

(30) Foreign Application Priority Data
Jul. 30, 2010 (KR) 10-2010-0074098

(51) Int. Cl. G02B 1/11; H01L 21/302; H01L 33/44

(52) U.S. Cl. CPC G02B 1/11; H01L 33/44; H01L 21/302
USPC 359/601; 438/29; 438/694

(57) ABSTRACT

A micro/nano combined structure, a manufacturing method of a micro/nano combined structure, and a manufacturing method of an optical device having a micro/nano combined structure integrated therewith, the method comprising: forming a micro structure on a substrate; depositing a metal thin film on the substrate on which the micro structure is formed; heat treating and transforming the metal thin film into metal particles; and using the metal particles as a mask to form a non-reflective nanostructure having a frequency below that of light wavelengths and a sharp wedge-shaped end, on the top surface of the substrate on which the micro structure is formed, and etching the front surface of the substrate on which the micro structure is formed. The manufacturing process is simple, light reflectivity that occurs wherein a difference in refractive indices of air and semiconductor material can be minimized, and is easily applied to the optical device field.

### TECHNICAL FIELD

The present invention disclosed herein relates to a micro/nano combined structure, a manufacturing method of the micro/nano combined structure, and a manufacturing method of an optical device having the micro/nano combined structure integrated therewith, and more particularly, to a micro/nano combined structure able to minimize Fresnel reflection and total reflection generated due to a difference between refractive indices of air and a semiconductor material by forming a sharp wedge-shaped or parabolic anti-reflective nanostructure with a subwavelength period on a microstructure through deposition of a metal thin film, heat treatment, and blanket etching after forming the microstructure on a substrate, a method of manufacturing the micro/nano combined structure, and a method of manufacturing an optical device integrated with the micro/nano combined structure.

### BACKGROUND ART

In general, reduction of an amount of reflection of light between two media having different refractive indices is very important issue to be addressed in optical devices such as solar cells, photodetectors, light emitting diodes, and transparent glass.

Such reflection of light may become a main cause of decreasing efficiency of an optical device and higher efficiency may be obtained as the reflection of light is minimized. Methods generally used to reduce the reflection of light may be broadly classified as two types.

The first is a method of reducing the possibility of generating total reflection by forming a micro-scale structure, and this corresponds to texturing, a microlens, or a micro grating pattern.

FIG. 1 is a conceptual view illustrating reflection and transmission of light incident on a structure having a micropattern formed thereon according to an embodiment of related art, in which there may be advantages in that the possibility of the light escaping to the outside through a structure 1 having a micropattern 1a formed thereon according to the embodiment of related art (solid line) may be increased, but there may be disadvantages in that Fresnel reflection due to a difference between refractive indices of a medium and air may not be overcome (dotted line).

The second is a method of gradually changing an effective refractive index between two media through a grating or non-periodic structure having a size shorter than a wavelength, in order to fundamentally reduce a loss caused by the difference between refractive indices thereof.

This is referred to as a “Moth eye” structure due to the resemblance to the shape of a moth's eye.

FIG. 2 is a conceptual view illustrating reflection and transmission of light incident on a structure 2 having a nanopattern 2a formed thereon according to another embodiment of related art, in which nearly 0% reflectance may be obtained with respect to a vertical incident angle because Fresnel reflection may rarely occur at an interface between a medium and air, but there may be disadvantages in that total reflection generated when the incident angle increases may not be removed.

As described above, in the case that a typical microstructure is used, total reflection may be reduced, but Fresnel reflection may be difficult to be reduced, and in the case in which a subwavelength nanostructure is used, Fresnel reflection may be reduced, but total reflection may not be reduced.

### DISCLOSURE

### Technical Problem

The present invention provides a micro/nano combined structure able to minimize Fresnel reflection and total reflection generated due to a difference between refractive indices of air and a semiconductor material by forming a sharp wedge-shaped or parabolic anti-reflective nanostructure with a subwavelength period on a microstructure through deposition of a metal thin film, heat treatment, and blanket etching after forming the microstructure on a substrate, a method of manufacturing the micro/nano combined structure, and a method of manufacturing an optical device integrated with the micro/nano combined structure.

### Technical Solution

In accordance with an exemplary embodiment of the present invention, a micro/nano combined nanostructure includes a microstructure formed on a substrate, wherein a sharp wedge-shaped anti-reflective nanostructure with a subwavelength period is formed on a top surface of the substrate having the microstructure formed thereon.

Herein, the anti-reflective nanostructure may be formed by heat treating a metal thin film deposited on the substrate having the microstructure formed thereon to transform into metal particles and etching an entire surface of the substrate having the microstructure formed thereon by using the metal particles as a mask.

The anti-reflective nanostructure may be formed by heat treating a buffer layer and a metal thin film sequentially deposited on the substrate having the microstructure formed thereon to transform into metal particles, blanket etching the buffer layer by using the metal particles as a mask to form a nanostructured buffer layer, and etching an entire surface of the substrate having the microstructure formed thereon by using the nanostructured buffer layer as a mask.

In accordance with another exemplary embodiment of the present invention, a method of manufacturing a micro/nano combined nanostructure includes: forming a microstructure on a substrate; depositing a metal thin film on the substrate having the microstructure formed thereon; heat treating the metal thin film to transform into metal particles; and etching an entire surface of the substrate having the microstructure formed thereon by using the metal particles as a mask to form a sharp wedge-shaped anti-reflective nanostructure with a subwavelength period on a top surface of the substrate having the microstructure formed thereon.

In accordance with another exemplary embodiment of the present invention, a method of manufacturing a micro/nano combined nanostructure includes: forming a microstructure on a substrate; sequentially depositing a buffer layer and a metal thin film on the substrate having the microstructure formed thereon; heat treating the metal thin film to transform into metal particles; blanket etching the buffer layer by using the metal particles as a mask to form a nanostructured buffer layer; and etching an entire surface of the substrate having the microstructure formed thereon by using the nanostructured buffer layer as a mask to form a sharp wedge-shaped anti-reflective nanostructure with a subwavelength period on a top surface of the substrate having the microstructure formed thereon.

Herein, the microstructure may include surface texturing, a microlens, or a micro grating pattern, and the surface texturing may denote forming random roughness on the surface thereof by using a wet or dry etching method.

The microlens may denote forming the shape of a lens having a diameter ranging from a few micrometers to a few tens of micrometers, and a manufacturing method thereof may generally include a method, in which the shape of a lens is formed by heat treating a patterned photoresist and then pattern transferred to the substrate, and additionally, may include various methods such as a method of selective oxidation of aluminum.

The micro grating pattern may be formed through etching the substrate by using a photoresist pattern having a size ranging from a few micrometers to a few tens of micrometers as a mask.

The buffer layer may be formed of silicon oxide (SiO₂) or silicon nitride (SiNₓ).

The metal thin film may be deposited with any one of silver (Ag), gold (Au), or nickel (Ni), or may be deposited by selecting metal to be transformed into metal particles with a subwavelength period after the heat treatment in consideration of surface tension with respect to the substrate.

The metal thin film may be deposited to have a thickness ranging from about 5 nm to about 100 nm or may be deposited by selecting a thickness at which the metal thin film is transformed into metal particles with a subwavelength period after the heat treatment.

The heat treatment may be performed at a temperature ranging from about 200° C. to about 900° C. or may be performed by selecting a temperature at which the metal thin film is transformed into metal particles with a subwavelength period after the heat treatment.

The anti-reflective nanostructure may be formed by plasma dry etching.

A desired aspect ratio may be obtained through adjusting a height and an angle of inclination of the anti-reflective nanostructure by controlling at least any one condition of gas flow, pressure, and driving voltage during the dry etching.

In accordance with another exemplary embodiment of the present invention, a method of manufacturing an optical device integrated with a micro/nano combined structure includes: sequentially stacking an n-type doping layer, an active layer, and a p-type doping layer, and then forming a microstructure on a top surface of a light-emitting part of the p-type doping layer excluding positions of p-type upper electrodes; stacking the p-type upper electrodes on a top surface of the p-type doping layer and stacking an n-type lower electrode on a bottom surface of the n-type doping layer; depositing a metal thin film on the top surface of the light-emitting part having the microstructure of the p-type doping layer formed thereon; heat treating the metal thin film to transform into metal particles; and etching an entire surface of the light-emitting part having the microstructure of the p-type doping layer formed thereon by using the metal particles as a mask to form a sharp wedge-shaped anti-reflective nanostructure with a subwavelength period on the top surface of the light-emitting part having the microstructure of the p-type doping layer formed thereon.

In accordance with another exemplary embodiment of the present invention, a method of manufacturing an optical device integrated with a micro/nano combined structure includes: sequentially stacking an n-type doping layer, an active layer, and a p-type doping layer, and then forming a microstructure on a top surface of a light-emitting part of the p-type doping layer; depositing a metal thin film on the top surface of the light-emitting part having the microstructure of the p-type doping layer formed thereon; heat treating the metal thin film to transform into metal particles; etching an entire surface of the light-emitting part having the microstructure of the p-type doping layer formed thereon by using the metal particles as a mask to form a sharp wedge-shaped anti-reflective nanostructure with a subwavelength period on the top surface of the light-emitting part having the microstructure of the p-type doping layer formed thereon; and stacking a transparent electrode on an entire surface of the p-type doping layer including the anti-reflective nanostructure, and then stacking a contact pad on a top surface of the transparent electrode excluding the light-emitting part and stacking an n-type lower electrode on a bottom surface of the n-type doping layer.

In accordance with another exemplary embodiment of the present invention, a method of manufacturing an optical device integrated with a micro/nano combined structure includes: sequentially stacking a bottom cell, a middle cell, and a top cell, and then stacking a p-type upper electrode on a top surface of one side of the top cell and stacking an n-type lower electrode on a bottom surface of the bottom cell; forming a microstructure on a top surface of the top cell excluding a region of the p-type upper electrode; depositing a metal thin film on the top surface of the top cell having the microstructure formed thereon; heat treating the metal thin film to transform into metal particles; and etching an entire surface of the top cell excluding the region of the p-type upper electrode by using the metal particles as a mask to form a sharp wedge-shaped anti-reflective nanostructure with a subwavelength period on the top surface of the top cell having the microstructure formed thereon excluding the region of the p-type upper electrode.

Herein, the bottom cell and the middle cell may be connected through a first tunnel junction, and the middle cell and the top cell may be connected through a second tunnel junction.

A buffer layer may be further included between the first tunnel junction and the middle cell.

In accordance with another exemplary embodiment of the present invention, a method of manufacturing an optical device integrated with a micro/nano combined structure includes: sequentially stacking an n-type doping layer, an optical absorption layer, and a p-type doping layer, and then stacking p-type upper electrodes on a top surface of the p-type doping layer excluding an optical absorption part and stacking an n-type lower electrode on a bottom surface of the n-type doping layer; forming a microstructure on a top surface of the optical absorption part of the p-type doping layer; depositing a metal thin film on the top surface of the optical absorption part of the p-type doping layer having the microstructure formed thereon; heat treating the metal thin film to transform into metal particles; and etching an entire surface of the optical absorption part of the p-type doping layer having the microstructure formed thereon by using the metal particles as a mask to form a sharp wedge-shaped anti-reflective nanostructure with a subwavelength period on the top surface of the optical absorption part of the p-type doping layer having the microstructure formed thereon.

In accordance with another exemplary embodiment of the present invention, a method of manufacturing an optical device integrated with a micro/nano combined structure includes: sequentially stacking an n-type doping layer, a distributed Bragg reflector layer, an active layer, and a p-type doping layer, and then forming a microstructure on a top surface of a light-emitting part of the p-type doping layer excluding a position of a p-type upper electrode; depositing a metal thin film on the top surface of the light-emitting part having the microstructure formed thereon; heat treating the metal thin film to transform into metal particles; and etching an entire surface of the light-emitting part of the p-type doping layer having the microstructure formed thereon by using the metal particles as a mask to form a sharp wedge-shaped anti-reflective nanostructure with a subwavelength period on the top surface of the light-emitting part of the p-type doping layer having the microstructure formed thereon.

Herein, the method may further include forming an n-type lower electrode on a bottom surface of the n-type doping layer, after forming the p-type upper electrode on one side of the p-type doping layer.

### Advantageous Effects

According to the foregoing micro/nano combined structure of the present invention, a method of manufacturing the micro/nano combined structure, and a method of manufacturing an optical device integrated with the micro/nano combined structure, since a sharp wedge-shaped or parabolic anti-reflective nanostructure with a subwavelength period may be formed on a microstructure through deposition of a metal thin film, heat treatment, and blanket etching after forming the microstructure on a substrate, a manufacturing process may be simplified, and an amount of reflection of light generated due to a difference between refractive indices of air and a semiconductor material may not only be minimized, but an anti-reflective grating structure with a subwavelength period may also be prepared at a low cost, and efficiency may be maximized when the micro/nano combined structure is integrated with an optical device such as solar cells, photodetectors, light emitting diodes, and transparent glass.

Also, according to the present invention, processing may be possible when a substrate has a step height, wafer-scale processing may be possible, and since a metal mask is used, masking function may be sufficiently performed regardless of a substrate material.

### DESCRIPTION OF DRAWINGS

FIG. 1 is a conceptual view illustrating reflection and transmission of light incident on a structure having a micropattern formed thereon according to an embodiment of related art;

FIG. 2 is a conceptual view illustrating reflection and transmission of light incident on a structure having a nanopattern formed thereon according to another embodiment of related art;

FIG. 3 is a sectional view illustrating a method of manufacturing a micro/nano combined structure according to a first embodiment of the present invention;

FIG. 4 is a conceptual view illustrating reflection and transmission of light incident on the micro/nano combined structure according to the first embodiment of the present invention;

FIG. 5 is scanning electron microscope (SEM) micrographs showing typical micro- and nano-patterned structures, and the micro/nano combined structure according to the first embodiment of the present invention;

FIG. 6 is a sectional view illustrating a method of manufacturing a micro/nano combined structure according to a second embodiment of the present invention;

FIG. 7 is a sectional view illustrating a method of manufacturing an optical device integrated with a micro/nano combined structure according to a third embodiment of the present invention;

FIG. 8 is a sectional view illustrating a method of manufacturing an optical device integrated with a micro/nano combined structure according to a fourth embodiment of the present invention;

FIG. 9 is a sectional view illustrating an optical device integrated with a micro/nano combined structure according to a fifth embodiment of the present invention;

FIG. 10 is a sectional view illustrating an optical device integrated with a micro/nano combined structure according to a sixth embodiment of the present invention;

FIG. 11 is a sectional view illustrating an optical device integrated with a micro/nano combined structure according to a seventh embodiment of the present invention;

FIG. 12 is a sectional view illustrating a method of manufacturing an optical device integrated with a micro/nano combined structure according to an eighth embodiment of the present invention;

FIG. 13 is a graph illustrating optical power of the optical device integrated with the micro/nano combined structure according to the eighth embodiment of the present invention; and

FIG. 14 is a sectional view illustrating a method of manufacturing an optical device integrated with a micro/nano combined structure according to a ninth embodiment of the present invention.

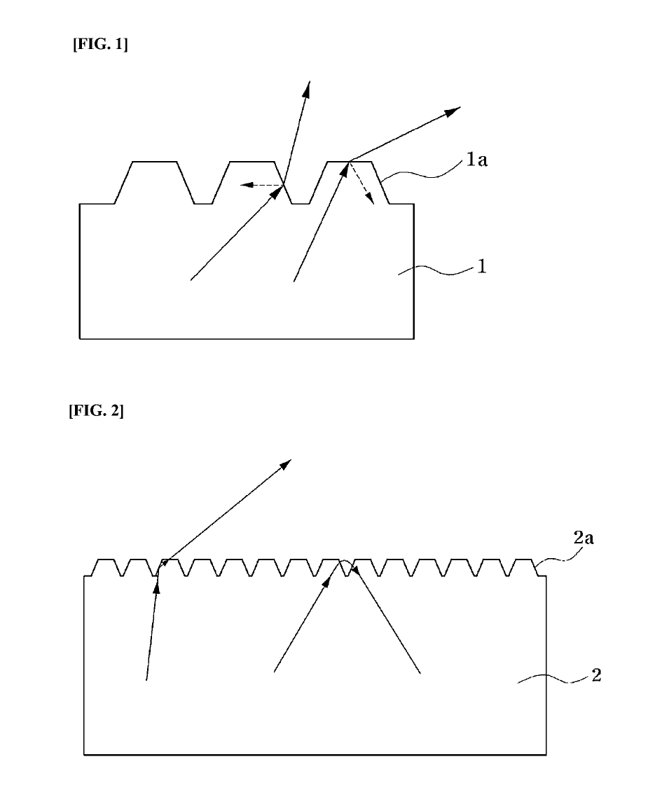

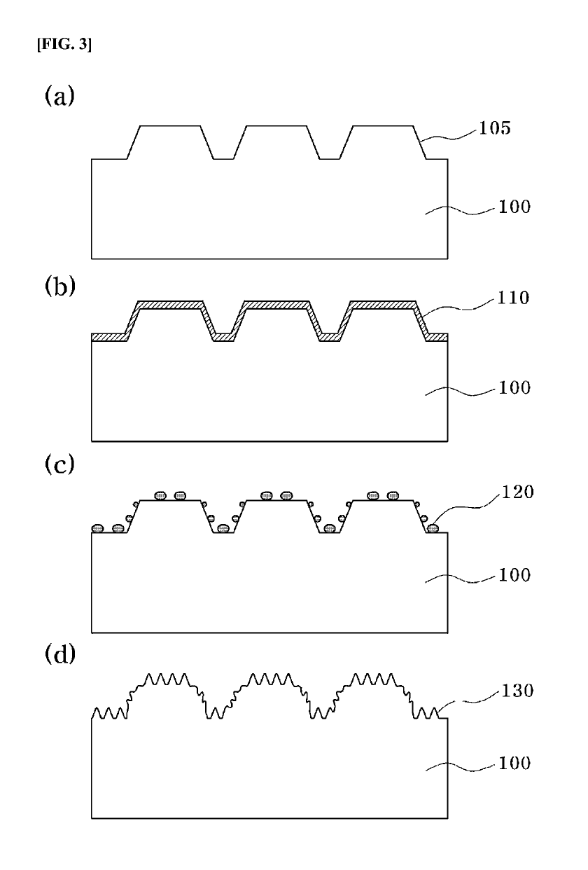

### BEST MODE

Hereinafter, preferred embodiments of the present invention will be described in detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

### First Embodiment

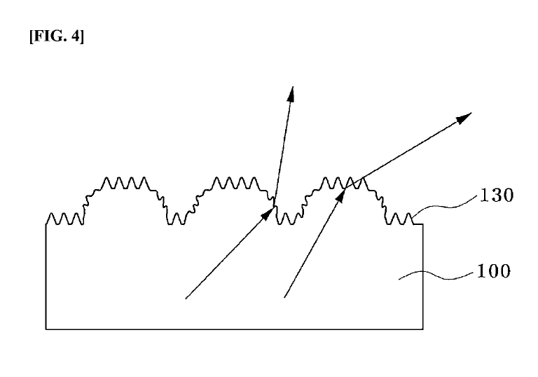

FIG. 3 is a sectional view illustrating a method of manufacturing a micro/nano combined structure according to a first embodiment of the present invention.

Referring to FIG. 3(a), a microstructure 105 is formed on a substrate 100 prepared in advance. Herein, the substrate 100, for example, may be formed of a semiconductor substrate (e.g., GaAs substrate or InP substrate), but the substrate 100 is not limited thereto, and any substrate may be used so long as a metal thin film 110 to be later described may be deposited on the substrate 100 including the microstructure 105, even in the case that the substrate is not the semiconductor substrate.

For example, the microstructure 105 may include surface texturing, a microlens, or a micro grating pattern.

The surface texturing, for example, denotes forming random roughness on the surface thereof by using a wet or dry etching method.

The microlens denotes forming the shape of a lens having a diameter ranging from a few micrometers to a few tens of micrometers, and a manufacturing method thereof may generally include a method, in which the shape of a lens is formed by heat treating a patterned photoresist and then pattern transferred to the substrate, and additionally, may include various methods such as a method of selective oxidation of aluminum.

The micro grating pattern may be formed through etching the substrate by using a photoresist pattern having a size ranging from a few micrometers to a few tens of micrometers as a mask.

Referring to FIG. 3(b), the metal thin film 110 is deposited on a top surface of the substrate 100 having the microstructure 105 formed thereon by using, for example, an E-beam evaporator or a thermal evaporator.

Herein, various metals, such as silver (Ag), gold (Au), and nickel (Ni), may be deposited as the metal thin film 110, and the metal thin film 110 may be deposited by selecting metal able to be transformed into metal particles (or metal granules) 120 (see FIG. 3(c)) with a subwavelength period after being subjected to a subsequent heat treatment process in consideration of surface tension with respect to the substrate 100.

Also, the metal thin film 110 may be deposited to have a thickness ranging from about 5 nm to about 100 nm and may be deposited by selecting a thickness at which the metal thin film 110 may be transformed into the metal particles 120 with a subwavelength period after the heat treatment.

Meanwhile, the deposition of the metal thin film 110, for example, is not limited to E-beam evaporation or thermal evaporation, and any apparatus, such as a sputtering machine, able to deposit metal in a thickness ranging from about 5 nm to about 100 nm may be used.

Referring to FIG. 3(c), the metal thin film 110, for example, is transformed into the metal particles 120 through a heat treatment by using a rapid thermal annealing (RTA) method.

At this time, the heat treatment may be performed at a temperature ranging from about 200° C. to about 900° C., and the heat treatment may be performed by selecting a temperature at which the metal thin film 110 may be transformed into the metal particles 120 with a subwavelength period after the heat treatment.

Referring to FIG. 3(d), an anti-reflective nanostructure 130 with a predetermined period (for example, about 100 nm to about 1000 nm) and a depth (for example, about 50 nm to about 600 nm), i.e., a subwavelength period, may be formed on the top surface of the substrate 100 itself including the microstructure 105 by performing, for example, a dry etching process on an entire surface of the substrate 100 including the metal particles 120.

The anti-reflective nanostructure 130 may be periodically and constantly arranged on the surface of the substrate 100 including the microstructure 105 and may be formed as a sharp wedge shape, e.g., a cone shape, in which a cross-sectional area decreases from the surface of the substrate 100 toward an air layer on an upper side thereof. However, the anti-reflective nanostructure 130 is not limited thereto, and for example, may be formed as a parabola, triangular pyramid, quadrangular pyramid, or polypyramid shape.

Meanwhile, the dry etching method, for example, may use plasma dry etching, but the dry etching method is not limited thereto, and a dry etching method that improves anisotropic etching characteristics and an etching rate by simultaneously using reactive gas and plasma, for example, a reactive ion etching (RIE) method or an inductively coupled plasma (ICP) etching method, in which plasma is generated by radio frequency (RF) power, may be used.

A desired aspect ratio may be easily obtained through adjusting a height and an angle of inclination of the anti-reflective nanostructure 130 by controlling at least any one condition of gas flow, pressure, and driving voltage during the dry etching.

FIG. 4 is a conceptual view illustrating reflection and transmission of light incident on the micro/nano combined structure according to the first embodiment of the present invention, in which Fresnel reflection and total reflection generated due to a difference between refractive indices of air and a semiconductor material may be minimized by the micro/nano combined structure of the present invention.

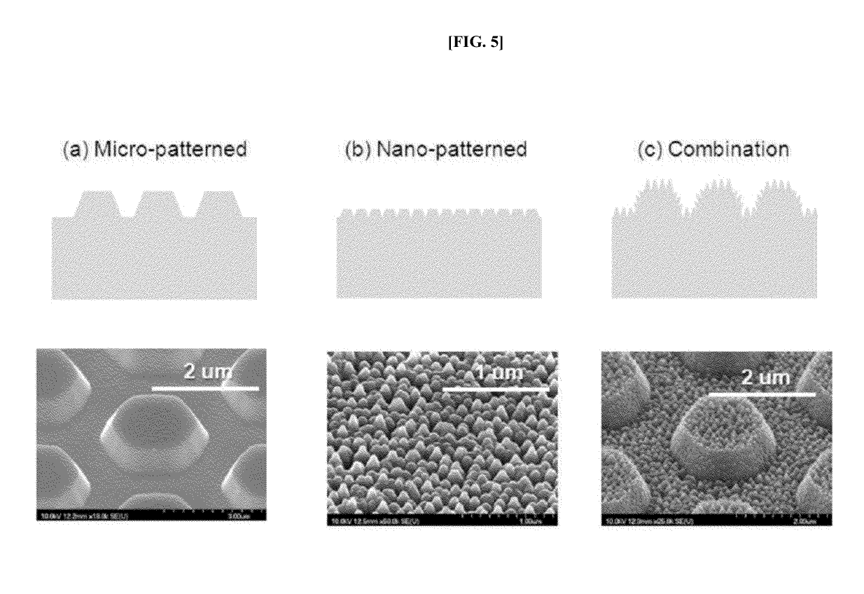

FIG. 5 is scanning electron microscope (SEM) micrographs showing (a) typical micro-patterned structure and (b) nano-patterned structure, and (c) the micro/nano combined structure prepared according to the first embodiment of the present invention, in which GaAs is used as the substrate 100 (see FIG. 3(a)) and it may be confirmed that a sharp wedge-shaped anti-reflective nanostructure may be formed on the substrate 100 having the microstructure 105 (see FIG. 3(a)) formed thereon.

### Second Embodiment

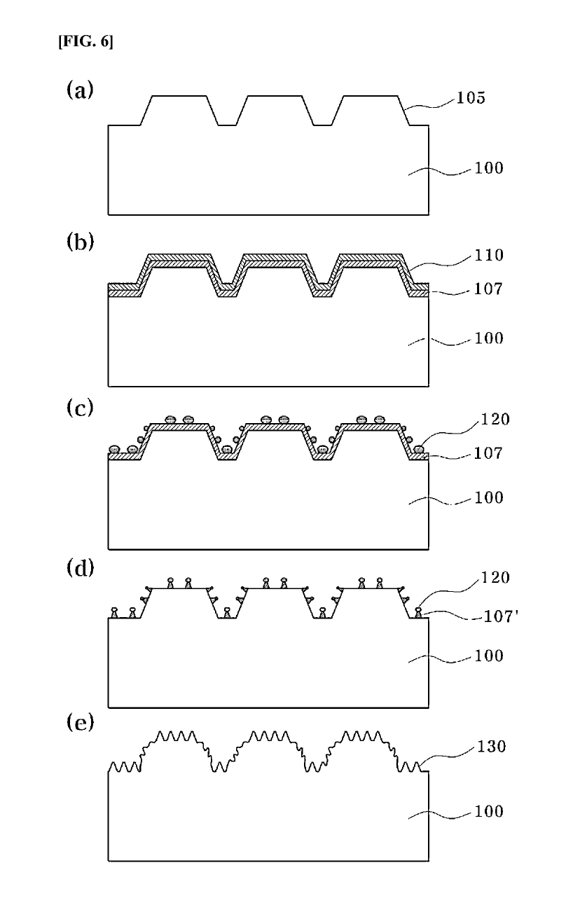

FIG. 6 is a sectional view illustrating a method of manufacturing a micro/nano combined structure according to a second embodiment of the present invention.

Referring to FIG. 6(a), a microstructure 105 is formed on a substrate 100 prepared in advance. Herein, the substrate 100, for example, may be formed of a semiconductor substrate (e.g., GaAs substrate or InP substrate), but the substrate 100 is not limited thereto, and any substrate may be used so long as a buffer layer 107 to be later described may be deposited on a top surface of the substrate 100 including the microstructure 105, even in the case that the substrate is not the semiconductor substrate.

Referring to FIG. 6(b), the buffer layer 107, for example, formed of silicon oxide (SiO₂) or silicon nitride (SiNₓ) is deposited on the top surface of the substrate 100 having the microstructure 105 formed thereon by, for example, plasma enhanced chemical vapor deposition (PECVD), thermal chemical vapor deposition (Thermal-CVD), or sputtering, and a metal thin film 110 is sequentially deposited by using, for example, an E-beam evaporator or a thermal evaporator.

Herein, the buffer layer 107, for example, is not limited to silicon oxide (SiO₂) or silicon nitride (SiNₓ), and any material may be used so long as the metal thin film 110 may be transformed into metal particles (or metal granules) 120 (see FIG. 6(c)) with a subwavelength period after a heat treatment by surface tension between the buffer layer 107 and the metal thin film 110.

Also, the buffer layer 107 may be deposited to have a thickness ranging from about 5 nm to about 500 nm, and the thickness of the buffer layer 107 must satisfy conditions, in which, first, the metal film 110 may be transformed into the metal particles 120 with a subwavelength period after the heat treatment, and second, the buffer layer 107 may become a nanostructured buffer layer 107′ (see FIG. 6(d)) allowing predetermined portions of the top surface of the substrate 100 including the microstructure 105 to be exposed through blanket etching by using the metal particles 120.

In general, in the case that the metal thin film 110 is heat treated to be transformed into the metal particles 120, a period and a size of the metal particles 120 may be changed by surface tension between the substrate 100 and the metal thin film 110. Therefore, in the case that a material of the substrate 100 is changed according to the purpose thereof, a thickness and a heat treatment temperature of the metal must be changed accordingly, and this may be difficult to be applied to actual applications.

Meanwhile, when the buffer layer 107 formed of silicon oxide (SiO₂) or silicon nitride (SiNₓ) is used, the surface tension between the buffer layer 107 and the metal thin film 110 does not change even in the case that the material of the substrate 100 is changed, and thus, the metal particles 120 may be reproducibly formed with no changes in the thickness and the heat treatment temperature of the metal.

Various metals, such as Ag, Au, and Ni, may be deposited as the metal thin film 110, and the metal thin film 110 may be deposited by selecting metal able to be transformed into metal particles 120 with a subwavelength period after being subjected to a subsequent heat treatment process in consideration of surface tension with respect to the substrate 100.

Also, the metal thin film 110 may be deposited to have a thickness ranging from about 5 nm to about 100 nm and may be deposited by selecting a thickness at which the metal thin film 110 may be transformed into the metal particles 120 with a subwavelength period after the heat treatment.

Meanwhile, the deposition of the metal thin film 110, for example, is not limited to E-beam evaporation or thermal evaporation, and any apparatus, such as a sputtering machine, able to deposit metal in a thickness ranging from about 5 nm to about 100 nm may be used.

Referring to FIG. 6(c), the metal thin film 110, for example, is transformed into the metal particles 120 through a heat treatment by rapid thermal annealing (RTA). At this time, the heat treatment may be performed at a temperature ranging from about 200° C. to about 900° C., and may be performed by selecting a temperature at which the metal thin film 110 may be transformed into the metal particles 120 with a subwavelength period after the heat treatment.

Referring to FIG. 6(d), the nanostructured buffer layer 107′ with a predetermined period (for example, about 100 nm to about 1000 nm) and a depth (for example, about 50 nm to about 600 nm), i.e., a subwavelength period, may be formed on the top surface of the substrate 100 including the microstructure 105 by performing, for example, a dry etching process on an entire surface of the substrate 100 including the buffer layer 107 and the metal particles 120.

The nanostructured buffer layer 107′ may not be aligned, but may be formed with a predetermined spacing.

Referring to FIG. 6(e), an anti-reflective nanostructure 130 with a subwavelength period is formed on the top surface of the substrate 100 including the microstructure 105 through blanket etching by using the nanostructured buffer layer 107′ as a mask. Thereafter, a residual buffer layer and the metal particles 120 are removed through wet etching.

The anti-reflective nanostructure 130 may be formed as a sharp wedge shape, e.g., a cone shape, in which a cross-sectional area decreases from the surface of the substrate 100 toward an air layer on an upper side thereof. However, the anti-reflective nanostructure 130 is not limited thereto, and for example, may be formed as a parabola, triangular pyramid, quadrangular pyramid, or polypyramid shape. In some cases, the anti-reflective nanostructure 130 may be formed as a truncated cone shape.

Meanwhile, the dry etching method may use plasma dry etching, but the dry etching method is not limited thereto, and a dry etching method that improves anisotropic etching characteristics and an etching rate by simultaneously using reactive gas and plasma, for example, a reactive ion etching (RIE) method or a inductively coupled plasma (ICP) etching method, in which plasma is generated by RF power, may be used.

A height and an angle of inclination of the anti-reflective nanostructure may be adjusted by controlling at least any one condition of gas flow, pressure, and driving voltage during the dry etching, and in particular, a desired aspect ratio may be easily obtained by controlling RF power.

In addition, a transparent electrode (not shown) may be further disposed between the substrate 100 and the buffer layer 107, and the transparent electrode, for example, may be deposited by using an E-beam evaporator, a thermal evaporator, or a sputter.

For example, any one of indium tin oxide (ITO), tin oxide (TO), indium tin zinc oxide (IZO), and indium zinc oxide (IZO) may be selected as a material of the transparent electrode.

Meanwhile, since all manufacturing processes other than a process of disposing the transparent electrode are the same as those of the foregoing second embodiment, the detailed description related thereto will be referred to the foregoing second embodiment. However, in the case that the transparent electrode is disposed between the substrate 100 and the buffer layer 107, the nanostructured buffer layer 107′ is formed on a top surface of the transparent electrode in the foregoing FIG. 6(d), a nanostructured transparent electrode is formed through blanket etching by using the nanostructured buffer layer 107′ as a mask in FIG. 6(e), and an anti-reflective nanostructure, in which a predetermined portion of the substrate also has a subwavelength period, is formed. Thereafter, a transparent electrode may be again deposited on the entire surface of the substrate 100 to connect the nanostructured transparent electrodes each other and thus, current may be allowed to be flown therebetween.

### Third Embodiment

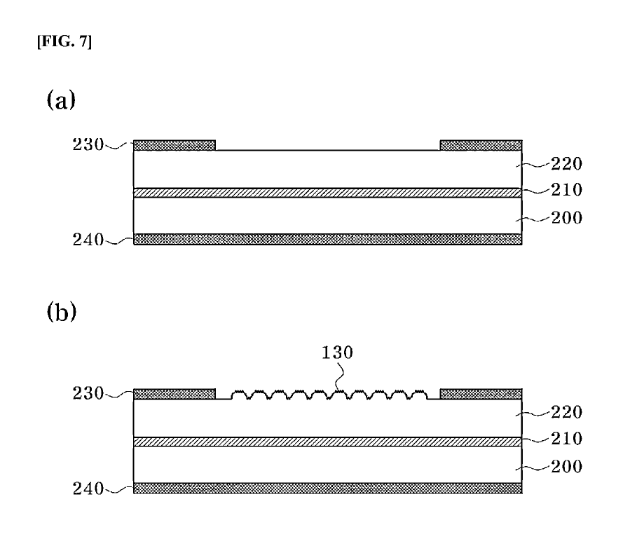

FIG. 7 is a sectional view illustrating a method of manufacturing an optical device integrated with a micro/nano combined structure according to a third embodiment of the present invention.

Referring to FIG. 7(a), the optical device has a structure of a general light-emitting device, and for example, the optical device may be formed by sequentially stacking an n-type doping layer 200, an active layer 210, and a p-type doping layer 220, and then stacking p-type upper electrodes 230 on a top surface of the p-type doping layer 220 excluding a light-emitting part and stacking an n-type lower electrode 240 on a bottom surface of the n-type doping layer 200. However, the optical device is not limited thereto.

Referring to FIG. 7(b), the anti-reflective nanostructure 130 formed according to the first or second embodiment of the present invention is integrated on a top surface of the light-emitting part of the p-type doping layer 220, and thus, the method of manufacturing an optical device integrated with an anti-reflective micro/nano combined structure according to the third embodiment of the present invention may be completed.

At this time, since the detailed description related to the method of forming the anti-reflective nanostructure 130 is the same as that of the foregoing first or second embodiment of the present invention, the detailed description related thereto will be omitted.

### Fourth Embodiment

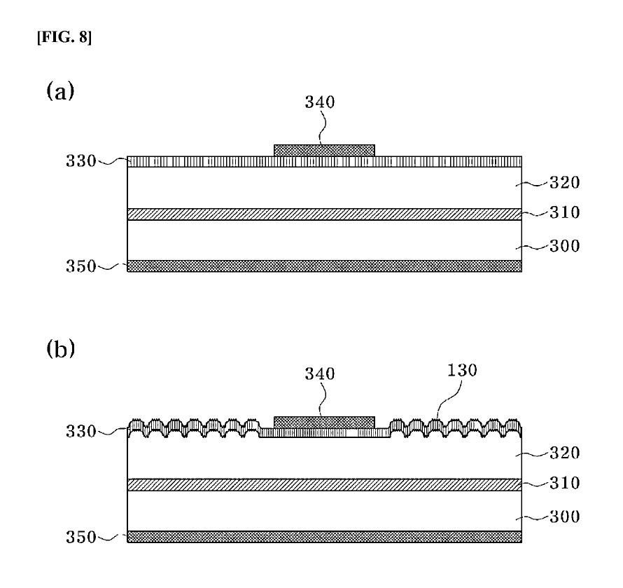

FIG. 8 is a sectional view illustrating a method of manufacturing an optical device integrated with a micro/nano combined structure according to a fourth embodiment of the present invention.

Referring to FIG. 8(a), the optical device has a structure of a general light-emitting device, and for example, the optical device may be formed by sequentially stacking an n-type doping layer 300, an active layer 310, and a p-type doping layer 320, and then sequentially stacking a transparent electrode 330 and a contact pad 340 on a top surface of the p-type doping layer 320 and stacking an n-type lower electrode 350 on a bottom surface of the n-type doping layer 300. However, the optical device is not limited thereto.

Referring to FIG. 8(b), before stacking the transparent electrode 330, the anti-reflective nanostructure 130 formed according to the first or second embodiment of the present invention is integrated on a top surface of the light-emitting part of the p-type doping layer 320, and thus, the method of manufacturing an optical device integrated with a micro/nano combined structure according to the fourth embodiment of the present invention may be completed.

At this time, since the detailed description related to the method of forming the anti-reflective nanostructure 130 is the same as that of the foregoing first or second embodiment of the present invention, the detailed description related thereto will be omitted.

Meanwhile, the transparent electrode 330 is stacked on an entire surface of the p-type doping layer 320 including the anti-reflective nanostructure 130 and the contact pad 340 is then stacked on a top surface of the transparent electrode 330 excluding the light-emitting part. At this time, since the transparent electrode 330 is deposited on the anti-reflective nanostructure 130, the shape thereof may be formed to be the same as that of the anti-reflective nanostructure 130.

### Fifth Embodiment

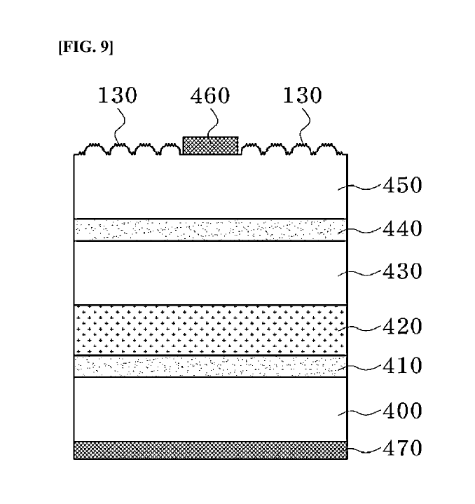

FIG. 9 is a sectional view illustrating an optical device integrated with a micro/nano combined structure according to a fifth embodiment of the present invention.

Referring to FIG. 9, the optical device is a general triple junction solar cell and has a structure in which germanium (Ge) having a bandgap of about 0.65 eV is used as a bottom cell 400, In_{0.08}Ga_{0.92}As having a bandgap near 1.4 eV is disposed thereon as a middle cell 430, and In_{0.56}Ga_{0.44}P having a bandgap of about 1.9 eV is disposed thereon as a top cell 450.

Each cells 410, 430, and 450 are electrically connected through first and second tunnel junctions 410 and 440, a p-type upper electrode 460 is formed on a top surface of one side of the top cell 450, and an n-type lower electrode 470 is formed on a bottom surface of the bottom cell 400.

In particular, the anti-reflective nanostructure 130 formed according to the first or second embodiment of the present invention is integrated on a top surface of the top cell 450 excluding a region of the p-type upper electrode 460, and thus, the method of manufacturing a triple junction solar cell, the optical device integrated with a micro/nano combined structure according to the fifth embodiment of the present invention, may be completed.

At this time, since the detailed description related to the method of forming the anti-reflective nanostructure 130 is the same as that of the foregoing first or second embodiment of the present invention, the detailed description related thereto will be omitted.

For example, a buffer layer 420 formed of InGaAs may be further included between the first tunnel junction 410 and the middle cell 430.

That is, in view of the absorption spectrum of sunlight, the top cell 450 absorbs up to the wavelength of about 650 nm, the middle cell 430 absorbs up to the wavelength of about 900 nm, and the bottom cell 400 absorbs up to the wavelength of about 1900 nm, and thus, the solar cell may have a structure able to absorb light over a wide bandwidth.

Herein, the method of manufacturing the anti-reflective nanostructure 130 is applied to the surface of the top cell 450 and thus, reflection of the incident light may be minimized and as a result, efficiency of the solar cell may be increased.

### Sixth Embodiment

FIG. 10 is a sectional view illustrating an optical device integrated with a micro/nano combined structure according to a sixth embodiment of the present invention.

Referring to FIG. 10, the optical device has a structure of a general photodetector, and for example, the optical device may be formed by sequentially stacking an n-type doping layer 500, an optical absorption layer 510, and a p-type doping layer 520, and then stacking p-type upper electrodes 530 on a top surface of the p-type doping layer 520 excluding an optical absorption part and stacking an n-type lower electrode 540 on a bottom surface of the n-type doping layer 500. However, the optical device is not limited thereto.

In particular, the anti-reflective nanostructure 130 formed according to the first or second embodiment of the present invention is integrated on a top surface of the optical absorption part of the p-type doping layer 520, and thus, the method of manufacturing an optical device integrated with a micro/nano combined structure according to the sixth embodiment of the present invention may be completed.

At this time, since the detailed description related to the method of forming the anti-reflective nanostructure 130 is the same as that of the foregoing first or second embodiment of the present invention, the detailed description related thereto will be omitted.

Herein, the method of manufacturing the anti-reflective nanostructure 130 is applied to a surface of the p-type doping layer 520 and thus, reflection of the incident light may be minimized and as a result, efficiency of the photodetector may be increased.

### Seventh Embodiment

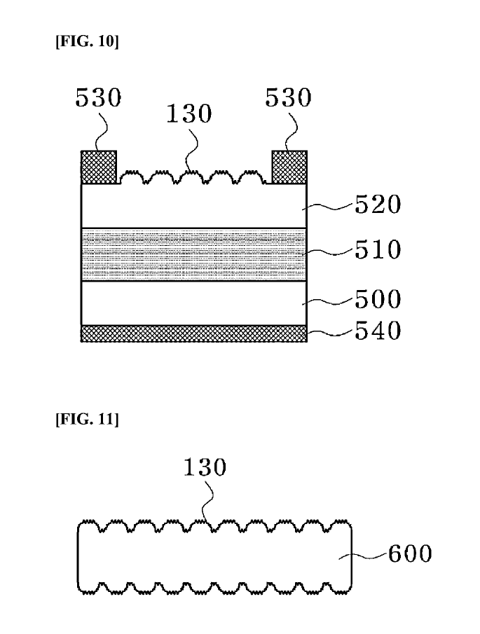

FIG. 11 is a sectional view illustrating an optical device integrated with a micro/nano combined structure according to a seventh embodiment of the present invention.

Referring to FIG. 11, the optical device is general transparent glass 600, and has a refractive index of about 1.5 and exhibits a transmittance of about 95% or more in a specific wavelength band. However, with respect to some applications such as solar cells, about 99% or more of transmittance may be required over a wide bandwidth and for this purpose, the method of manufacturing the anti-reflective nanostructure 130 formed according to the foregoing first or second embodiment of the present invention may be used.

That is, the anti-reflective nanostructure 130 formed according to the foregoing first or the second embodiment of the present invention is integrated on a top surface of the transparent glass 600, and thus, high transmittance may be obtained over a wider bandwidth. Also, the anti-reflective nanostructure 130 may be integrated under as well as on the transparent glass 600 and thus, high transmittance may be obtained over a wider bandwidth.

### Eighth Embodiment

FIG. 12 is a sectional view illustrating a method of manufacturing an optical device integrated with a micro/nano combined structure according to an eighth embodiment of the present invention.

Referring to FIG. 12, the optical device has a structure of a general light-emitting device, i.e., a light-emitting diode (LED), and for example, the optical device may be formed by sequentially stacking an n-type doping layer (n-GaAs) 700, a distributed Bragg reflector (DBR) layer (AlAs/AlGaAs) 710, an active layer 720, and a p-type doping layer 730, and then stacking a p-type upper electrode 740 on a top surface of the p-type doping layer 730 excluding a light-emitting part and stacking an n-type lower electrode 750 on a bottom surface of the n-type doping layer 700. However, the optical device is not limited thereto.

In particular, the anti-reflective nanostructure 130 formed according to the foregoing first or the second embodiment of the present invention is integrated on a top surface of the light-emitting part of the p-type doping layer 730, and thus, the method of manufacturing an optical device integrated with a micro/nano combined structure according to the eighth embodiment of the present invention may be completed.

At this time, since the detailed description related to the method of forming the anti-reflective nanostructure 130 is the same as that of the foregoing first or second embodiment of the present invention, the detailed description related thereto will be omitted.

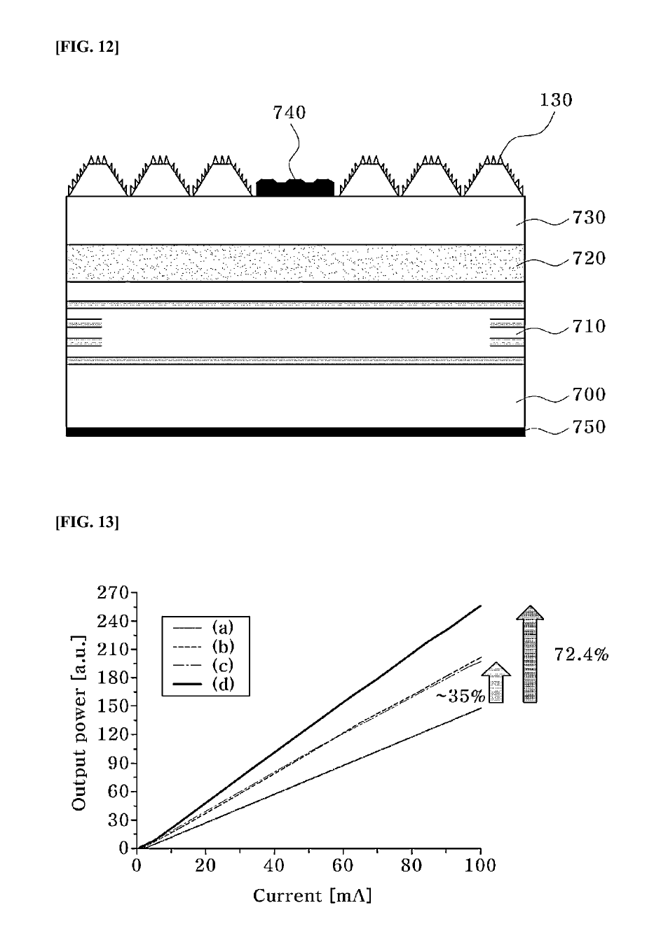

FIG. 13 is a graph illustrating optical power of the optical device integrated with the micro/nano combined structure according to the eighth embodiment of the present invention, in which FIG. 13(a) illustrates a typical optical device without an anti-reflective nanostructure, FIG. 13(b) illustrates a typical optical device only with an anti-reflective nanopattern, FIG. 13(c) illustrates a typical optical device only with an anti-reflective micropattern, and FIG. 13(d) illustrates the optical device having a micro/nano combined structure according to the eighth embodiment of the present invention, and it may be confirmed that the power thereof is increased to about 35% to about 72.4% in comparison to those of typical optical devices and the output wavelength thereof is almost not changed.

### Ninth Embodiment

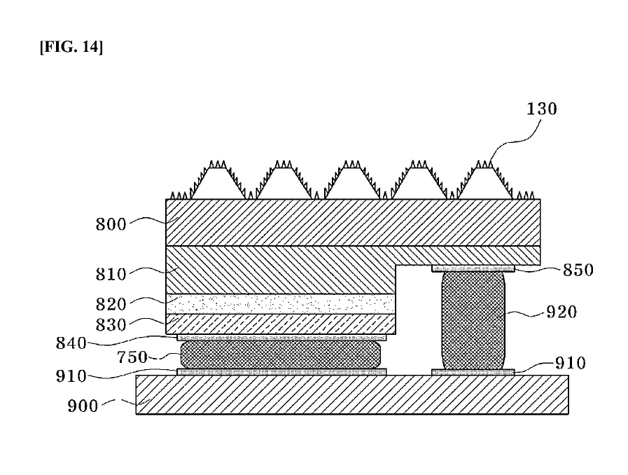

FIG. 14 is a sectional view illustrating a method of manufacturing an optical device integrated with a micro/nano combined structure according to a ninth embodiment of the present invention.

Referring to FIG. 14, the optical device has a structure of a flip-chip bonding type GaN-based light-emitting diode (LED), in which a buffer layer formed of gallium nitride (GaN) and a n-type gallium nitride (n-GaN) layer 810 are formed on a sapphire substrate 800 formed of an Al₂O₃-based component.

Metal organic chemical vapor deposition (MOCVD) is generally used in order to grow thin films of group 3 elements on the sapphire substrate 800 and layers are formed while growth pressure is maintained in a range of about 200 torr to about 650 torr.

Thereafter, the n-type gallium nitride layer 810 is grown and an active layer 820 is then grown on the n-type gallium nitride layer 810. The active layer 820 is a light-emitting region that is a semiconductor layer having a quantum well formed of InGaN, for example, a multi-quantum well (MQW) layer. The active layer 820 is grown and then a p-type gallium nitride (p-GaN) layer 830 is subsequently grown. The p-type gallium nitride layer 830, for example, is formed of an AlGaN or InGaN component.

The p-type gallium nitride layer 830 is a layer in contrast with the n-type gallium nitride layer 810, in which the n-type gallium nitride layer 810 provides electrons to the active layer 820 by the voltage applied from the outside. In contrast, the p-type gallium nitride layer 830 provides holes to the active layer 820 by the voltage applied from the outside and thus, holes and electrons are combined in the active layer 820 to generate light.

Metal having high reflectivity is formed on the p-type gallium nitride layer 830 to form a p-type electrode 840 including the function of a reflecting plate. Herein, an electrode pad may be further formed on the p-type electrode 840.

Thereafter, etching is performed up to the n-type gallium nitride layer 810 to open and an n-type electrode 850 is then formed on the n-type gallium nitride layer 810.

The LED having the foregoing configuration is mounted on a silicon (Si) submount 900 in the form of a flip chip, in which metal bumps 920 (e.g., Au bumps) are used between the p-type and n-type electrodes 840 and 850 on the submount 900 and reflective layers 910 formed at corresponding positions to electrically bond them.

When the power is applied to the LED through the submount 900, electrons and holes are combined in the active layer 820 of the flip-chip bonded LED having the foregoing structure to generate light.

A portion of the light generated from the active layer 820 is emitted to the outside through the sapphire substrate 800 and another portion of the light is reflected from the p-type gallium nitride layer 830, the p-type electrode 840, and the reflective layer 910 formed on the submount 900 and then emitted to the outside.

In particular, in the case that the LED is flip-chip bonded, since the light generated from the active layer 820 is emitted to the outside through the sapphire substrate 800 directly or after the reflection, luminous efficiency may increase in comparison to a light-emitting diode generating light from a top surface of a semiconductor.

In addition, the anti-reflective nanostructure 130 formed according to the foregoing first or the second embodiment of the present invention is integrated on an externally exposed surface of the sapphire substrate 800 so as to minimize an amount of reflection of the light generated due to the difference between refractive indices of air and a semiconductor material during the emission of the light to the outside through the sapphire substrate 800, and thus, the method of manufacturing an optical device integrated with a micro/nano combined structure according to the ninth embodiment of the present invention may be completed.

At this time, since the detailed description related to the method of forming the anti-reflective nanostructure 130 is the same as that of the foregoing first or second embodiment of the present invention, the detailed description related thereto will be omitted.

While the present invention has been particularly shown and described with reference to exemplary embodiments related to the foregoing method of manufacturing a micro/nano combined structure and method of manufacturing an optical device integrated with a micro/nano combined structure according to the present invention, it will be understood that the present invention is not limited thereto and various changes in form and details may be made therein without departing from the spirit and scope of the present invention as defined by the following claims.

1. A micro/nano combined nanostructure comprising a microstructure formed on a substrate,
wherein a sharp wedge-shaped anti-reflective nanostructure with a subwavelength period is formed on a top surface of the substrate having the microstructure formed thereon.

2. The micro/nano combined nanostructure of claim 1, wherein the anti-reflective nanostructure is formed by heat treating a metal thin film deposited on the substrate having the microstructure formed thereon to transform into metal particles and etching an entire surface of the substrate having the microstructure formed thereon by using the metal particles as a mask.

3. The micro/nano combined nanostructure of claim 1, wherein the anti-reflective nanostructure is formed by heat treating a buffer layer and a metal thin film sequentially deposited on the substrate having the microstructure formed thereon to transform into metal particles, blanket etching the buffer layer by using the metal particles as a mask to form a nanostructured buffer layer, and etching an entire surface of the substrate having the microstructure formed thereon by using the nanostructured buffer layer as a mask.

4. (canceled)

5. A method of manufacturing a micro/nano combined nanostructure, the method comprising:
forming a microstructure on a substrate;
sequentially depositing a buffer layer and a metal thin film on the substrate having the microstructure formed thereon;
heat treating the metal thin film to transform into metal particles;
blanket etching the buffer layer by using the metal particles as a mask to form a nanostructured buffer layer; and
etching an entire surface of the substrate having the microstructure formed thereon by using the nanostructured buffer layer as a mask to form a sharp wedge-shaped anti-reflective nanostructure with a subwavelength period on a top surface of the substrate having the microstructure formed thereon.

6. The method of claim 5, wherein the buffer layer is formed of silicon oxide (SiO₂) or silicon nitride (SiNₓ).

7. The method of claim 5, wherein the metal thin film is deposited with any one of silver (Ag), gold (Au), or nickel (Ni), or deposited by selecting metal to be transformed into metal particles with a subwavelength period after the heat treatment in consideration of surface tension with respect to the substrate.

8. The method of claim 5, wherein the metal thin film is deposited to have a thickness ranging from about 5 nm to about 100 nm or deposited by selecting a thickness at which the metal thin film is transformed into metal particles with a subwavelength period after the heat treatment.

9. The method of claim 5, wherein the heat treatment is performed at a temperature ranging from about 200° C. to about 900° C. or is performed by selecting a temperature at which the metal thin film is transformed into metal particles with a subwavelength period after the heat treatment.

10. The method of claim 5, wherein the anti-reflective nanostructure is formed by plasma dry etching.

11. The method of claim 10, wherein a desired aspect ratio is obtained through adjusting a height and an angle of inclination of the anti-reflective nanostructure by controlling at least any one condition of gas flow, pressure, and driving voltage during the dry etching.

12-13. (canceled)

14. A method of manufacturing an optical device integrated with a micro/nano combined structure, the method comprising:
sequentially stacking a bottom cell, a middle cell, and a top cell, and then stacking a p-type upper electrode on a top surface of one side of the top cell and stacking an n-type lower electrode on a bottom surface of the bottom cell;
forming a microstructure on a top surface of the top cell excluding a region of the p-type upper electrode;
depositing a metal thin film on the top surface of the top cell having the microstructure formed thereon;
heat treating the metal thin film to transform into metal particles; and
etching an entire surface of the top cell excluding the region of the p-type upper electrode by using the metal particles as a mask to form a sharp wedge-shaped anti-reflective nanostructure with a subwavelength period on the top surface of the top cell having the microstructure formed thereon excluding the region of the p-type upper electrode.

15. The method of claim 14, wherein the bottom cell and the middle cell are connected through a first tunnel junction, and the middle cell and the top cell are connected through a second tunnel junction.

16. The method of claim 15, wherein a buffer layer is further included between the first tunnel junction and the middle cell.

17. (canceled)

18. A method of manufacturing an optical device integrated with a micro/nano combined structure, the method comprising:
sequentially stacking an n-type doping layer, a distributed Bragg reflector layer, an active layer, and a p-type doping layer, and then forming a microstructure on a top surface of a light-emitting part of the p-type doping layer excluding a position of a p-type upper electrode;
depositing a metal thin film on the top surface of the light-emitting part having the microstructure formed thereon;
heat treating the metal thin film to transform into metal particles; and
etching an entire surface of the light-emitting part of the p-type doping layer having the microstructure formed thereon by using the metal particles as a mask to form a sharp wedge-shaped anti-reflective nanostructure with a subwavelength period on the top surface of the light-emitting part of the p-type doping layer having the microstructure formed thereon.

19. The method of claim 18, further comprising forming an n-type lower electrode on a bottom surface of the n-type doping layer, after forming the p-type upper electrode on one side of the p-type doping layer.
